(19) United States
(12) Patent Application Publication
(10) Pub. No.: US 2006/0223199 A1
(43) Pub. Date: Oct. 5, 2006

(54) Semiconductor device and manufacturing method thereof

(76) Inventor: Mamoru Ando, Gunma (JP)

Correspondence Address: FISH & RICHARDSON P.C., P.O. BOX 1022, MINNEAPOLIS, MN, 55440-1022, US

(21) Appl. No.: 11/385,332

(22) Filed: Mar. 20, 2006

(30) Foreign Application Priority Data
Mar. 29, 2005 (JP) P2005-094529

(51) Int. Cl. H01L 21/00

(52) U.S. Cl. 438/3

(57) ABSTRACT

By simultaneously forming via holes 35 for forming through electrodes 27 and 28 to be provided in second regions 13 and 14 and isolation trenches 30 for separating a first region 12 from the second regions 13 and 14, positioning of the via holes 35 and the isolation trenches 30 is omitted.

Priority is claimed to Japanese Patent Application Number JP2005-094529 filed on Mar. 29, 2005, the disclosure of which is incorporated herein by reference in its entirety.

### BACKGROUND OF THE INVENTION

1. Field of the Invention

The present invention relates to a method for manufacturing a semiconductor device, and more particularly relates to a method for manufacturing a semiconductor device according to a wafer level chip size package.

2. Description of the Related Art

A semiconductor device having a transistor element formed on a silicon substrate generally has a configuration as shown in FIG. 11. Reference numeral 1 is a silicon substrate, reference numeral 2 is an island such as a heat sink, on which the silicon substrate 1 is mounted, reference numeral 3 is a lead terminal, and reference numeral 4 is a resin for sealing.

As shown in FIG. 11, the silicon substrate 1 having a transistor element formed thereon is fixed to and mounted on the island 2 such as a copper base heat sink by use of a solder material 5 such as a solder. Moreover, a bonding wire is used to electrically connect a base electrode and an emitter electrode of the transistor element to the lead terminal 3 disposed on a periphery of the silicon substrate 1. A lead terminal connected to a collector electrode is integrally formed with the island and is electrically connected by mounting the silicon substrate on the island. Thereafter, transfer molding is performed by use of the thermosetting resin 4 such as an epoxy resin.

A resin-molded semiconductor device is usually mounted on a mounting substrate such as a glass epoxy substrate and electrically connected to another semiconductor devices and circuit elements which are mounted on the mounting substrate. Accordingly, the semiconductor device is treated as one component for performing predetermined circuit operations.

Meanwhile, considering a ratio of a semiconductor chip area actually having functions to a mounting area as an effective area ratio, it is understood that the resin-molded semiconductor device has a very low effective area ratio. The low effective area ratio causes most of the mounting area to be a dead space which is not directly related to a semiconductor chip having functions. Thus, the low effective area ratio interferes with high-density miniaturization of a mounting substrate 30.

Particularly, the problem described above is obvious in a semiconductor device having a small package size. For example, as shown in FIG. 12, a maximum size of a semiconductor chip mounted on SC-75A shape according to EIAJ standard is 0.40 mm×0.40 mm. When this semiconductor chip is resin-molded as shown in FIG. 12, the size of the entire semiconductor device is set to 1.6 mm×1.6 mm. A chip area of the semiconductor device is 0.16 mm², and a mounting area for mounting the semiconductor device is 2.56 mm² considering the mounting area to be approximately the same as an area of the semiconductor device. Thus, an effective area ratio of the semiconductor device is about 6.25%. Consequently, most of the mounting area is a dead space which is not directly related to the semiconductor chip area having functions.

As to a mounting substrate used in recent electronic devices, for example, a personal computer, a portable information processing device, a video camera, a portable telephone, a digital camera, a liquid crystal TV and the like, along with miniaturization of a main body of the electronic device, the mounting substrate used therein also tends to be densified and miniaturized.

However, in the semiconductor device described above, the large dead space interferes with miniaturization.

Meanwhile, the inventors of the present application have proposed Japanese Patent Application Publication No. Hei 10 (1998)-12651 as a conventional technology for improving an effective area ratio. As shown in FIG. 13, the conventional technology includes: a semiconductor substrate 60; an active element formation region 61 in which an active element is formed; an external connection electrode 62 for external connection, which is one of electrodes of the active element formed in the active element formation region 61; other external connection electrodes 63 and 64 which are electrically isolated from the active element formation region 61 and set a part of the substrate 60 to be an external electrode of the other electrode of the active element; and connection 65 for connecting the other electrode of the active element to the other external connection electrodes 63 and 64. In a surface of the active element formation region 61, a P+ type base region 71, an N+ type emitter region 72, and an N+ type guard ring diffusion region 73 are provided. An insulating film 74 covers the surface, and a base electrode 75, an emitter electrode 76 and a connection electrode 77 are provided. A resin layer 78 is provided on the insulating film 74 and integrally supports the active element formation region 61 and the other external connection electrodes 63 and 64. This technology is described in Japanese Patent Application Publication No. Hei 10 (1998)-12651.

However, in the above-described semiconductor device of a chip size package, due to a structure in which the semiconductor substrate 60 is divided by slit holes 80, the semiconductor substrate 60 is required to be supported and fixed on the same plane by the resin layer 78. However, since the resin layer 78 is attached to the insulating film 74 and has an even thickness, there is a significant problem from a practical standpoint that sufficient strength has not yet been obtained.

Moreover, since the slit holes 80 are formed from a rear surface of the semiconductor substrate 60, there is no mark to be a reference. Thus, there also remains a problem that positioning in formation of slit holes is difficult.

### SUMMARY OF THE INVENTION

The present invention was made in consideration for the foregoing problems. The present invention provides a method for manufacturing a semiconductor device of a wafer level chip size package, which is most suitable for practical application.

The present invention provides a method of manufacturing a semiconductor device. The method includes forming an epitaxial layer on an upper surface of a semiconductor substrate having, on its principal surface, a first region for forming a circuit element and a plurality of second regions disposed so as to be equally spaced apart from the first region in a periphery of the first region, forming the circuit element on the epitaxial layer in the first region, forming step parts on boundaries between the first region and the second regions in the epitaxial layer, forming via holes that reach the semiconductor substrate from a surface in the second regions of the epitaxial layer, forming isolation trenches that reach the semiconductor substrate from the step parts, and forming through electrodes made of metal in the via holes, forming connection for electrically connecting electrodes of the circuit element to the through electrodes on a surface of the epitaxial layer, and improving adhesion to the step parts by forming a resin layer which integrally supports the first region and the second regions on the surface of the epitaxial layer, and reducing a thickness of the semiconductor substrate by grinding the substrate from its rear surface, exposing the through electrodes and the isolation trenches from rear surfaces of the second regions, electrically separating the semiconductor substrate in the first region from the semiconductor substrate in the second regions, and forming external connection electrodes made of the semiconductor substrate in the second regions.

### BRIEF DESCRIPTION OF THE DRAWINGS

FIG. 1 is a cross-sectional view showing a semiconductor device completed by use of a manufacturing method of an embodiment of the present invention.

FIG. 2 is a cross-sectional view showing a method for manufacturing a semiconductor device according to an embodiment of the present invention.

FIG. 3 is a cross-sectional view showing the method for manufacturing a semiconductor device according to the embodiment of the present invention.

FIG. 4 is a cross-sectional view showing the method for manufacturing a semiconductor device according to the embodiment of the present invention.

FIG. 5 is a cross-sectional view showing the method for manufacturing a semiconductor device according to the embodiment of the present invention.

FIG. 6 is a cross-sectional view showing the method for manufacturing a semiconductor device according to the embodiment of the present invention.

FIG. 7 is a cross-sectional view showing the method for manufacturing a semiconductor device according to the embodiment of the present invention.

FIG. 8 is a cross-sectional view showing the method for manufacturing a semiconductor device according to the embodiment of the present invention.

FIG. 9 is a cross-sectional view showing the method for manufacturing a semiconductor device according to the embodiment of the present invention.

FIG. 10 is a plan view showing a method for manufacturing a semiconductor device according to another embodiment of the present invention.

FIG. 11 is a cross-sectional view showing a structure of a conventional semiconductor device.

FIG. 12 is a plan view showing a structure of a conventional semiconductor device.

FIG. 13 is a cross-sectional view showing a structure of a conventional semiconductor device.

### DESCRIPTION OF THE EMBODIMENTS

With reference to the drawings, embodiments of the present invention will be described below.

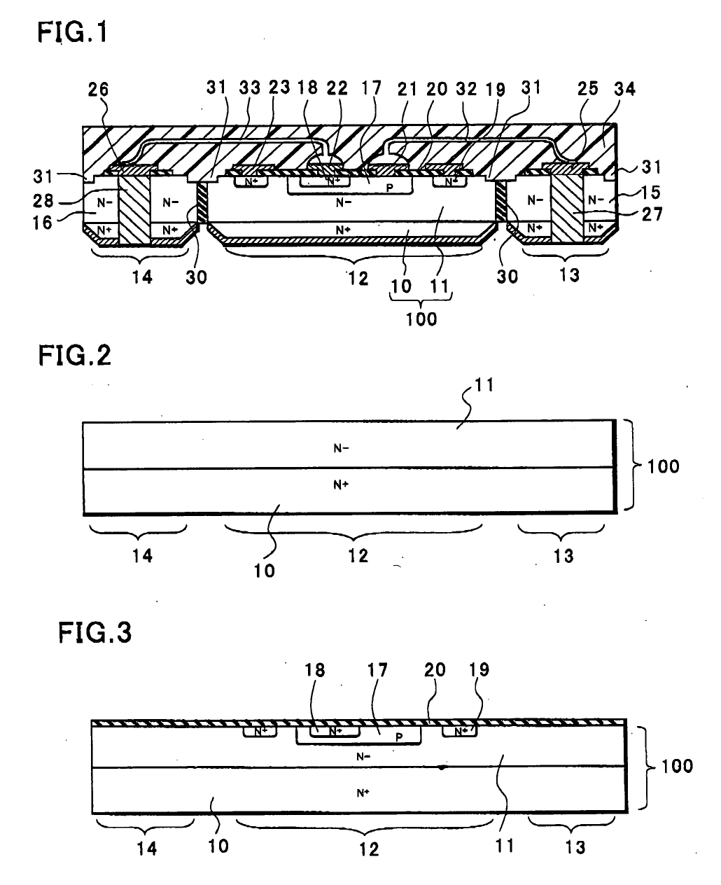

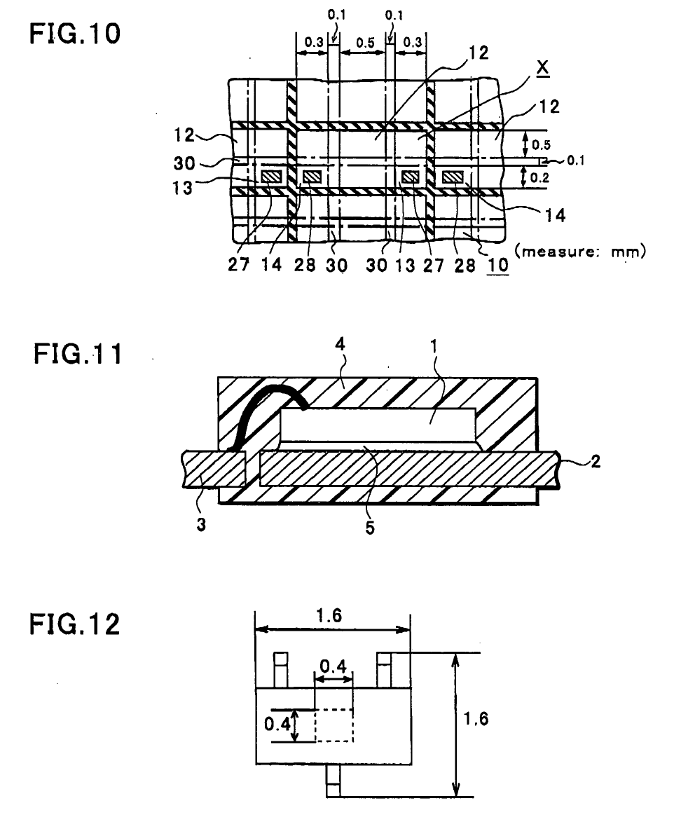

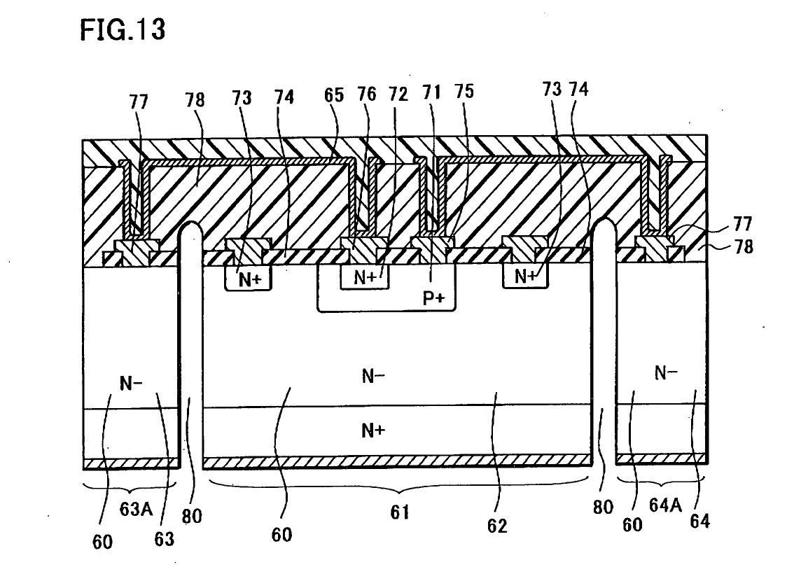

FIG. 1 is a cross-sectional view showing a semiconductor device completed by use of a manufacturing method of the embodiment of the present invention. FIGS. 2 to 9 are cross-sectional views showing a method for manufacturing a semiconductor device according to the embodiment of the present invention. FIG. 10 is a plan view showing a relationship in arrangement of electrodes in a semiconductor device according to an embodiment of the present invention.

As shown in FIG. 1, the semiconductor device completed by use of the manufacturing method of the embodiment of the present invention includes: a semiconductor substrate having a first region and a second region; a circuit element provided in the first region and a plurality of electrodes connected to the circuit element; an external connection electrode having a metal through electrode buried in the second region; isolation trenches for separating the semiconductor substrate between the first region and the second region; connections for electrically connecting the electrodes to the external connection electrode; step parts which expose the semiconductor substrate and are provided on surfaces of the first and second regions of the semiconductor substrate adjacent to the isolation trenches; and a resin layer which integrally supports the semiconductor substrate on the surfaces of the first and second regions of the semiconductor substrate including the step parts.

A substrate 100 is obtained by providing an N− type epitaxial layer 11 on an N+ type semiconductor substrate 10. The N+ type semiconductor substrate 10 is an N+ type single crystal silicon substrate. On the substrate 10, an N− type epitaxial layer 11 is formed by use of an epitaxial growth technology. A first region 12 in the center of the substrate 100 is set to be an active element formation region where an active circuit element (hereinafter circuit element) such as a power MOSFET and a transistor is formed. Second regions 13 and 14 on both sides of the first region 12 are set to be external connection electrode regions 15 and 16 to which electrodes of the circuit element are connected.

If the circuit element is a transistor, the epitaxial layer 11 is a collector region, and a P type base region 17, an N+ type emitter region 18 and an N+ type guard ring region 19 are formed in a surface of the epitaxial layer 11. A surface of the circuit element is covered with an oxide film 20. Through respective contact holes, a base electrode 21, an emitter electrode 22 and a guard ring 23 are formed by sputtering aluminum.

On surfaces of the second regions 13 and 14, connection electrodes 25 and 26 are similarly formed, which perform connection to the circuit element. Moreover, through electrodes 27 and 28 are formed, which penetrate the second regions 13 and 14 from the surfaces to rear surfaces thereof. The through electrodes 27 and 28 are made of metal such as copper and are exposed on the rear surfaces of the second regions 13 and 14. Therefore, the external connection electrodes are actually formed of the connection electrodes 25 and 26 on the surfaces of the second regions 13 and 14 and the through electrodes 27 and 28. Since all the electrodes are made of metal, a leading-out resistance value can be lowered.

Isolation trenches 30 electrically and mechanically separate the first region 12 from the second regions 13 and 14, and are formed by etching the semiconductor substrate 10.

In step parts 31, the epitaxial layer 11 of the semiconductor substrate 10 in peripheries of the first region 12 and the second regions 13 and 14 are etched and exposed. The step parts 31 are provided so as to be adjacent to the isolation trenches 30. Furthermore, the step parts 31 are similarly provided the outside of the second regions 13 and 14. All the step parts 31 are provided for the purpose of improving adhesion to a resin layer 34.

The electrodes of the circuit element, in other words, the base electrode 21 and the emitter electrode 22 are connected to the connection electrodes 25 and 26 of the external connection electrodes by bonding with thin metal wires 32 and 33. As the connections, a glass epoxy substrate having wiring previously formed thereon or the like may be used besides the above.

The surface of the substrate 100 is integrally covered with a resin layer 34. The resin layer 34 integrally supports the first region 12 and the second regions 13 and 14 of the substrate 100, which are separated by the isolation trenches 30, so as to hold the same plane. Moreover, the resin layer 34 also protects the thin metal wires 32 and 33.

The resin layer 34 improves adhesion by coming into direct contact with the epitaxial layer 11 of the semiconductor substrate 10 in the step parts 31. As the resin layer 34, a polyimide resin is preferable and a silicon resin and an epoxy resin may be combined and used.

In the structure described above, the step parts 31, the surface of the epitaxial layer 11, the oxide film 20 and the respective electrodes of the circuit element, the connection electrodes 25 and 26 form stair-like steps. Accordingly, an area of adhesion to the resin layer 34 can be increased. Thus, the adhesion to the resin layer 34 can be improved. Particularly, the resin layer 34 can be formed to have the largest thickness in the portions where the isolation trenches 30 are formed. Moreover, since the isolation trenches 30 are filled with insulators, moisture-absorption characteristics can also be improved. Furthermore, the step parts 31 provided the outside of the second regions 13 and 14 similarly lead to improvement in the moisture-absorption characteristics.

With reference to FIGS. 2 to 10, description will be given of a method for manufacturing a semiconductor device according to an embodiment of the present invention.

The method for manufacturing a semiconductor device according to the embodiment of the present invention includes the steps of forming an epitaxial layer on an upper surface of a semiconductor substrate having, on its principal surface, a first region 12 for forming a circuit element and a plurality of second regions 13 and 14 disposed so as to be equally spaced apart from the first region 12 in a periphery of the first region 12; forming a circuit element on the epitaxial layer 11 in the first region 12; forming step parts on boundaries between the first region 12 and the second regions 13 and 14 in the epitaxial layer 11; forming via holes that reach the semiconductor substrate 10 from the surface in the second regions 13 and 14 in the epitaxial layer 11, forming isolation trenches 30 that reach the semiconductor substrate 10 from the step parts 31, and forming through electrodes made of metal in the via holes; forming connections for electrically connecting electrodes of the circuit element to the through electrodes in the surface of the epitaxial layer 11; improving adhesion to the step parts 31 by forming a resin layer 34 which integrally supports the first region 12 and the second regions 13 and 14 on the surface of the epitaxial layer 11; and reducing the thickness of the semiconductor substrate 10 by grinding the substrate from its rear surface, exposing the through electrodes and the isolation trenches from rear surfaces of the second regions 13 and 14, electrically separating the semiconductor substrate 10 in the first region 12 from the semiconductor substrate 10 in the second regions 13 and 14, and forming external connection electrodes formed of the substrate 100 in the second regions 13 and 14.

First, as shown in FIG. 2, an epitaxial layer 11 is formed on an upper surface of a semiconductor substrate 10 having, on its principal surface, a first region 12 for forming a circuit element and a plurality of second regions 13 and 14 disposed so as to be equally spaced apart from the first region 12 in a periphery of the first region 12.

As shown in FIG. 2, on an N+ type semiconductor substrate 10 made of N+ type single crystal silicon, the N− type epitaxial layer 11 is formed by use of an epitaxial growth technology, thus preparing a substrate 100. The substrate 100 is divided into the first region 12, in which an active circuit element (hereafter circuit element) such as a power MOSFET and a transistor is formed, and the second regions 13 and 14, in which external connection electrodes are formed.

Next, as shown in FIG. 3, the circuit element is formed on the epitaxial layer 11 in the first region 12.

After an insulating film 20 such as a Si oxide film, which is formed by a thermal oxidation film or CVD method, is formed on the N− type epitaxial layer 11 on the semiconductor substrate 10, an opening is formed in a part of the insulating film 20 to expose the N− type epitaxial layer 11. After Ptype impurities such as boron (B) are selectively implanted into the N− type epitaxial layer 11 in the exposed region, thermal diffusion is performed to form an island-shaped base region 17 on the N−type epitaxial layer 11 in the first region 12.

After the base region 17 is formed, the insulating film 20 is formed again on the first region 12. An opening is formed in the insulating film 20 in a part of the base region 17, and the base region 17 is partially exposed. N+type impurities such as phosphorus (P) and antimony (Sb) are selectively implanted into the exposed base region 17. Thereafter thermal diffusion is performed. Thus, an emitter region 18 of a transistor is formed. In this embodiment, simultaneously with formation of the emitter region 18, a ring-shaped N+ type guard ring region 19 which surrounds the base region 17 is formed.

On the surface of the substrate 100, the insulating film 20 such as a silicon oxide film and a silicon nitride film is formed.

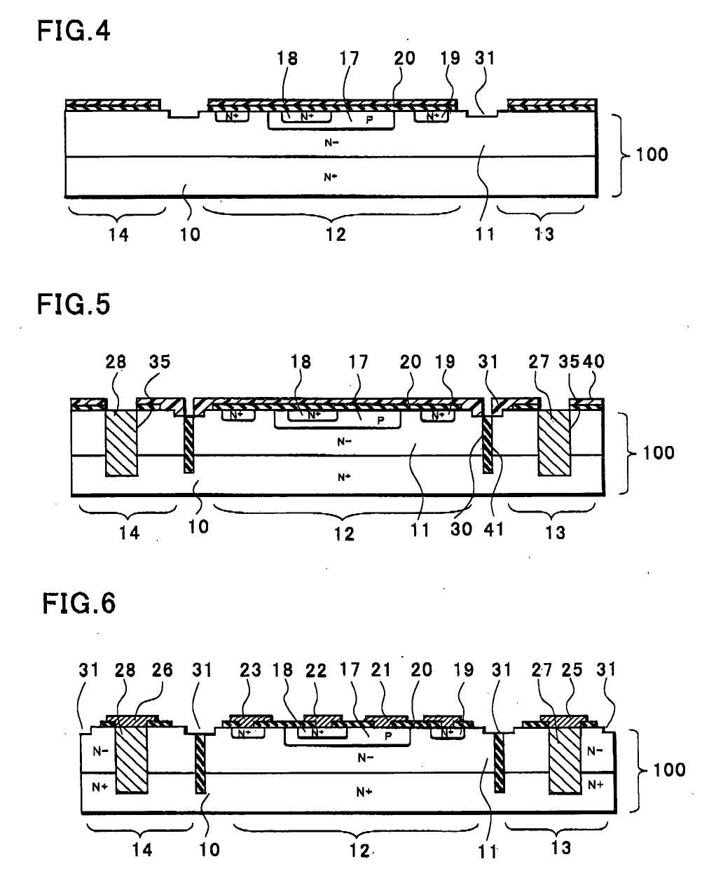

Furthermore, as shown in FIG. 4, step parts 31 are formed on boundaries between the first region 12 and the second regions 13 and 14 in the epitaxial layer 11.

In this step, the step parts 31 are formed by removing the insulating film 20 on the epitaxial layer 11 in regions on the boundaries between the first region 12 and the second regions 13 and 14 and by etching the surface of the epitaxial layer 11. In this event, the step parts 31 may be simultaneously formed in the epitaxial layer 11 in the outside portions of the second regions 13 and 14. By forming the step parts 31, the periphery of the first region 12 and the peripheries of the second regions 13 and 14 are exposed from the insulating film 20. Furthermore, the step parts 31, the surface of the epitaxial layer 11, the oxide film 20 and the respective electrodes of the circuit element, the connection electrodes 25 and 26 form stair-like steps. Accordingly, an area of adhesion to a resin layer can be increased. Thus, the area of the adhesion to the resin layer 34 can be made larger.

Furthermore, as shown in FIG. 5, in the second regions 13 and 14 in the epitaxial layer 11, via holes 35 that reach the semiconductor substrate 10 from the surface are formed and isolation trenches 30 that reach the semiconductor substrate 10 from the step parts 31 are formed. Moreover, through electrodes 27 and 28 made of metal are formed in the via holes 35.

The epitaxial layer 11 is dry-etched from its surface by using a resist 40 as a mask. Thus, the via holes 35 are formed, each of which has a thickness (or a width) of about 70 μm and a length (or a depth) of about 80 μm. As etching gas used in dry etching, gas containing at least SF₇, O₂ or C₄F₈ is used. The via holes 35 are formed so as to reach the semiconductor substrate 10 from the surface. As a specific shape of the via holes 35, a cylindrical shape or a rectangular columnar shape may be used.

In this step, simultaneously with formation of the via holes 35, the isolation trenches 30 are formed so as to reach the semiconductor substrate 10 from the step parts 31 by using the resist 40 as a mask. Specifically, the isolation trenches 30 are formed by dry-etching the epitaxial layer 11 from the surface so as to have a width of 20 to 100 μm and a length (or a depth) of about 80 μm. Accordingly, the via holes 35 and the isolation trenches 30 are masked with the same resist 40. Thus, a self-alignment effect is achieved, and positioning of the via holes 35 and the isolation trenches 30 is no longer required. Here, since the via hole 35 and the isolation trench 30 have different widths, etching depths are slightly different from each other. For example, the larger the width is, the deeper the depth gets.

Next, the isolation trenches 30 are selectively filled with an insulating film 41 such as a CVD oxide film.

Furthermore, the through electrodes 27 and 28 are formed in the via holes 35. The through electrodes 27 and 28 can be formed by plating or sputtering.

In the case where the through electrodes 27 and 28 are formed by plating, first, a seed layer (not shown), which is made of Cu and has a thickness of about several hundred nm, is formed on inner walls of the via holes 35 and on the entire surface of the oxide film 20 on the epitaxial layer 11. Next, electrolytic plating is performed by use of the seed layer as an electrode. Thus, the through electrodes 27 and 28 made of Cu are formed on the inner walls of the via holes 35.

Although, here, the via holes 35 are completely filled with Cu formed by plating, the filling may be incomplete. Specifically, cavities may be provided in the via holes 35.

Subsequently, as shown in FIG. 6, electrodes of the circuit element are formed. Cu on the oxide film 20 is removed, and a base contact hole for exposing the surface of the base region 17 and an emitter contact hole for exposing the surface of the emitter region 18 are formed by etching. In this embodiment, since the guard ring region 19 is formed, a guard ring contact hole for exposing the surface of the guard ring region 19 is simultaneously formed.

Thereafter, on the base region 17, the emitter region 18, the through electrodes 27 and 28 and the guard ring region 19, all of which are exposed by the base contact hole, the emitter contact hole, external connection contact holes and the guard ring contact hole, a metal material such as aluminum is selectively deposited. Thus, a base electrode 21, an emitter electrode 22, connection electrodes 25 and 26, and a guard ring 23 are selectively formed. Between the through electrodes 27 and 28 and the connection electrodes 25 and 26, barrier metal may be provided. For example, only Ti is formed and Al may be formed thereon. Alternatively, TiN is formed on Ti and Al may be formed thereon.

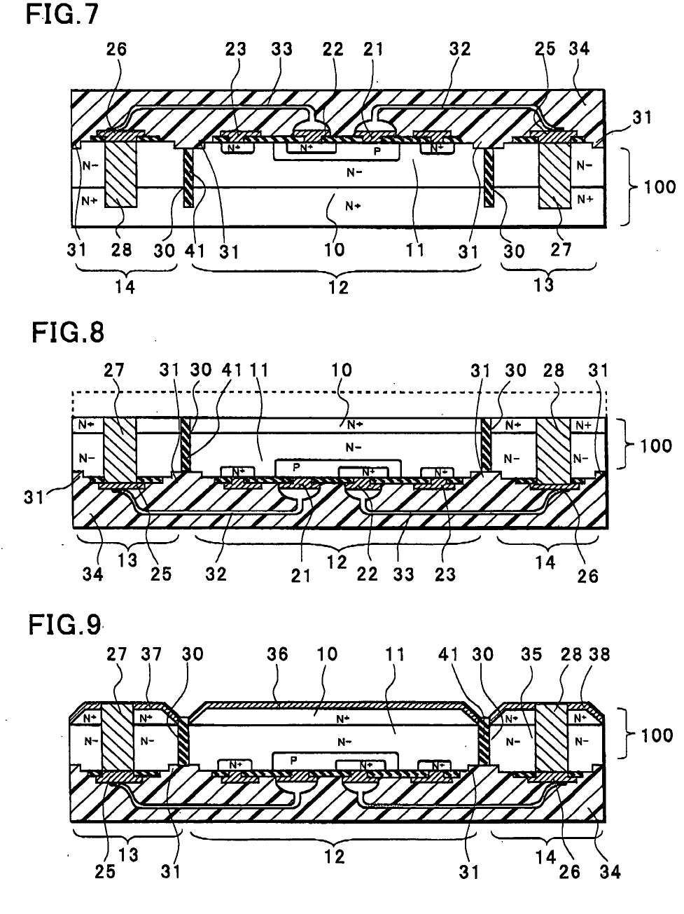

Furthermore, as shown in FIG. 7, connections 32 and 33 for electrically connecting the electrodes of the circuit element to the through electrodes 27 and 28 are formed on the surface of the epitaxial layer 11. Thereafter, a resin layer 34 which integrally supports the first region 12 and the second regions 13 and 14 is formed on the surface of the epitaxial layer 11. Thus, the resin layer 34 adheres to the step parts 31.

The connection electrodes 25 and 26 corresponding to the base electrode 21 and the emitter electrode 22 are connected thereto by bonding with thin metal wires 32 and 33. Note that, instead of the thin metal wires 32 and 33 as the connections, it is also possible to use a wiring substrate obtained by forming wiring in a substrate such as a glass epoxy substrate, a ceramic substrate, an insulated metal substrate, a phenol substrate and a silicon substrate. Here, in FIG. 7, wire bonding is performed immediately above the through electrodes 27 and 28. However, in the case where the via holes 35 for forming the through electrodes are not completely filled and hollow, and thin films are formed on the inner walls thereof, the connection electrodes may be extended to positions shifted from the via holes and wire bonding may be performed there.

The resin layer 34 is formed so as to insulate the connection 32 and 33 for connecting the base electrode 17 and the emitter electrode 18 of the transistor to the connection electrodes 25 and 26 as described above from the substrate 100. Moreover, the resin layer 34 is formed so as to integrally support the first region 12 and the second regions 13 and 14 when the first region 12 is mechanically separated from the second regions 13 and 14. As the resin layer 34, one including adhesive properties and insulating properties may be used, and, for example, a polyimide resin is preferable .

On the surface of the substrate 100, a polyimide resin having a thickness of 2 μm to 50 μm is applied by use of a spinner, for example. After burning for a predetermined period of time, the resin layer 34 having its surface polished and flattened is formed.

Furthermore, as shown in FIG. 8, the substrate 100 is ground from its rear surface and the thickness thereof is reduced. Thereafter, the through electrodes 27 and 28 and the isolation trenches 30 are exposed from rear surfaces of the second regions 13 and 14. Subsequently, the substrate 100 in the first region 12 and the substrate 100 in the second regions 13 and 14 are electrically separated from each other. Thus, external connection electrodes made of the substrate 100 in the second regions 13 and 14 are formed.

The surface of the substrate 100 is attached to a wafer support by use of wax and the like, and the substrate 100 is back-grind from its rear surface to remove an unnecessary portion thereof. Accordingly, the thickness of the semiconductor substrate 10 is reduced to about 400 μm to about 100 μm. In this event, the through electrodes 27 and 28 and the isolation trenches 30 are exposed from the rear surface of the semiconductor substrate 10. Accordingly, the first region 12, in which the circuit element is formed, and the second regions 13 and 14, in which the through electrodes 27 and 28 are provided, are automatically and electrically separated from each other. Moreover, the substrate 100 in the first region 12 and in the second regions 13 and 14 is mechanically and integrally supported by the resin layer 34 described above. Therefore, since the through electrodes 27 and 28 reach the rear surface of the semiconductor substrate 10 from the surface of the epitaxial layer 11, leading-out resistance of the electrodes can be significantly reduced. In FIG. 8, the through electrodes and the isolation trenches seem to have the same depth. However, in reality, the narrower the holes are, the shallower the holes get. Thus, if grinding and back etching are performed until the shallower one is exposed, all the through electrodes and the isolation trenches can be exposed.

Here, as shown in FIG. 10, the isolation trenches 30 are provided at positions where the first region 12 having the circuit element formed on the substrate 100 is mechanically and electrically separated from the second regions 13 and 14 in which the through electrodes 27 and 28 to be the external connection electrodes are buried in approximately centers thereof (the region indicated by dashed lines). The width of the isolation trench 30 is set to about 0.1 mm, for example, since it is required to maintain insulating properties with the adjacent regions 12 to 14 after separation thereof. The first region 12 is formed to have a size of 0.5 mm×0.5 mm, and the second regions 13 and 14 are set to have a size of 0.3 mm×0.2 mm. Finally, a transistor cell X including the first region 12 and the second regions 13 and 14, which are formed on the substrate 100, is divided into pieces by dicing in shaded portions. Thus, a semiconductor device is completed.

According to the embodiment of the present invention, as shown in FIG. 9, an external connection layer 36 for a collector electrode is provided on the rear surface of the first region 12 of the substrate 100. Moreover, an external connection electrode layer 37 for a base electrode and an external connection electrode layer 38 for an emitter electrode are provided on the rear surfaces of the second regions 13 and 14 of the substrate 100. The respective external connection electrode layers 36 to 38 are chamfered and etched at the isolation trenches 30 and therearound of the substrate 100 and are formed by plating metal suitable for soldering. Although the respective external connection electrodes layers 36 to 38 are arranged in a triangle shape in order to prevent short-circuiting in soldering, the external connection electrodes (external connection electrodes layers) may be linearly arranged.

In the method for manufacturing a semiconductor device according to the embodiment of the present invention, the via holes and the isolation trenches can be simultaneously formed from the surface of the epitaxial layer. Accordingly, the via holes and the isolation trenches are formed in a self-alignment manner. Thus, positioning of the through electrodes formed in the via holes and the isolation trenches is no longer required.

Moreover, as a result, the isolation trenches are surely formed in the step parts having strength and adhesion to the resin layer. Thus, the first region and the second regions can be supported and fixed on the same plane.

Furthermore, in the step parts, stair-like steps are formed in both of the first and second regions of the semiconductor substrate. Moreover, the resin layer is formed to have the largest thickness in the regions of the isolation trenches. Thus, an area of adhesion of the resin layer to the resin layer in the peripheries of the first and second regions of the semiconductor substrate can be increased. The strength of the resin layer itself can also be increased most. In addition, the isolation trenches are filled with insulator. Thus, moisture-absorption characteristics from the outside can also be significantly improved.

Furthermore, by simultaneously forming the isolation trenches and the via holes, the number of steps can be reduced.

Furthermore, by forming the through electrodes by use of metal, a leading-out resistance value is lowered.

What is claimed is:

1. A method of manufacturing a semiconductor device, comprising the steps of:
forming an epitaxial layer on an upper surface of a semiconductor substrate having, on its principal surface, a first region for forming a circuit element and a plurality of second regions disposed so as to be equally spaced apart from the first region in a periphery of the first region;
forming the circuit element on the epitaxial layer in the first region;
forming step parts on boundaries between the first region and the second regions in the epitaxial layer;
forming via holes that reach the semiconductor substrate from a surface in the second regions of the epitaxial layer, forming isolation trenches that reach the semiconductor substrate from the step parts, and forming through electrodes made of metal in the via holes;
forming connection for electrically connecting electrodes of the circuit element to the through electrodes on a surface of the epitaxial layer, and improving adhesion to the step parts by forming a resin layer which integrally supports the first region and the second regions on the surface of the epitaxial layer; and
reducing a thickness of the semiconductor substrate by grinding the substrate from its rear surface, exposing the through electrodes and the isolation trenches from rear surfaces of the second regions, electrically separating the semiconductor substrate in the first region from the semiconductor substrate in the second regions, and forming external connection electrodes made of the semiconductor substrate in the second regions.

2. The method for manufacturing a semiconductor device, according to claim 1, wherein the through electrodes are formed by plating copper in the via holes.

3. The method for manufacturing a semiconductor device, according to claim 1, wherein the step parts are formed so as to surround the first and second regions of the semiconductor substrate, respectively.

4. The method for manufacturing a semiconductor device, according to claim 1, wherein the isolation trenches are filled with insulators.
